(19) United States
(12) Patent Application Publication
(10) Pub. No.: US 2011/0148777 A1
(43) Pub. Date: Jun. 23, 2011

(54) METHOD FOR BONDING FPC ONTO BASEBOARD, BONDING ASSEMBLY, AND TOUCH SCREEN

(75) Inventor: KAI MENG, Shenzhen (CN)

(73) Assignees: INNOCOM TECHNOLOGY (SHENZHEN) CO., LTD., Shenzhen City (CN); INNOLUX DISPLAY CORP., Miao-Li County (TW)

(21) Appl. No.: 12/702,227

(22) Filed: Feb. 8, 2010

(30) Foreign Application Priority Data
Dec. 18, 2009 (CN) 200910311812.7

(51) Int. Cl. G06F 3/041; H05K 1/02; B32B 37/02

(52) U.S. Cl. 345/173; 174/259; 156/325

(57) ABSTRACT

A method for bonding a flexible printed circuit (FPC) onto a baseboard is provided. The baseboard includes a bonding region having a plurality of first electrodes, and a protective layer covering the bonding region. The FPC includes a plurality of second electrodes. The method includes aligning the FPC with the bonding region of the baseboard, positioning an ACF between the FPC and the baseboard, and pressing the FPC towards the baseboard such that an end of a conductive particle abuts against the second electrode of the FPC, and an opposite end of the conductive particle penetrates the protective layer and contacts the first electrodes.

### BACKGROUND

1. Technical Field

The disclosure relates to flexible printed circuits (FPCs); and particularly to a method for bonding an FPC onto a baseboard, a bonding assembly, and a touch screen manufactured using the method.

2. Description of Related Art

With developments in flat panel display (FPD) and touch screen technologies, touch screens are widely used in devices such as notebooks, personal digital assistants (PDAs), video cameras, and the like.

A frequently used touch screen includes a touch panel driven by a driving circuit, which is generally formed on a printed circuit board (PCB). The touch panel is electrically connected to the PCB via a flexible printed circuit (FPC).

The touch panel includes a substrate, and a detection assembly formed on the substrate. The detection assembly includes a plurality of conductive lines for detecting contact on the touch panel by a user's finger or stylus. Ends of the conductive lines extend to a predetermined region located at an edge of the substrate, and are configured as soldering pads. The soldering pads enable the FPC to be electrically attached thereon via solder material. Moreover, a protective layer is formed on the detection assembly to prevent damage by external forces or agents.

During manufacture of the touch screen, a portion of the protective layer covering the predetermined region of the touch panel is removed by etching, so as to bare the soldering pads for bonding to the FPC. However, such etching process may impair adjacent elements of the soldering pads within the touch panel, and the need for the etching process increases the overall manufacturing cost of the touch screen.

What is needed, therefore, is a method for bonding a flexible printed circuit onto a baseboard, and a bonding assembly, which can overcome the described limitations.

### BRIEF DESCRIPTION OF THE DRAWINGS

The components in the drawings are not necessarily drawn to scale, the emphasis instead being placed upon clearly illustrating the principles of at least one embodiment. In the drawings, like reference numerals designate corresponding parts throughout the various views.

FIG. 1 is an exploded view of a touch screen according to an exemplary embodiment of the present disclosure, the touch screen including a touch panel and an FPC.

FIG. 2 is an assembled view of the touch screen of FIG. 1.

FIG. 3 is an enlarged cross-section of the touch screen illustrated in FIG. 2, taken along line III-III thereof.

FIGS. 4-6 illustrate successive stages in an exemplary method for bonding an FPC onto a touch panel.

### DETAILED DESCRIPTION

Reference will now be made to the drawings to describe certain exemplary embodiments of the present disclosure in detail.

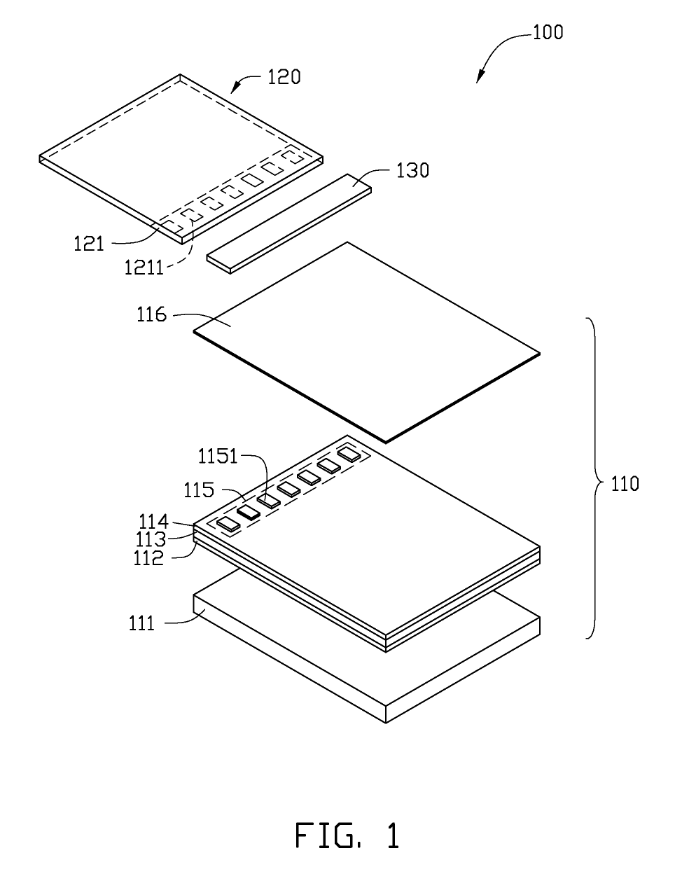

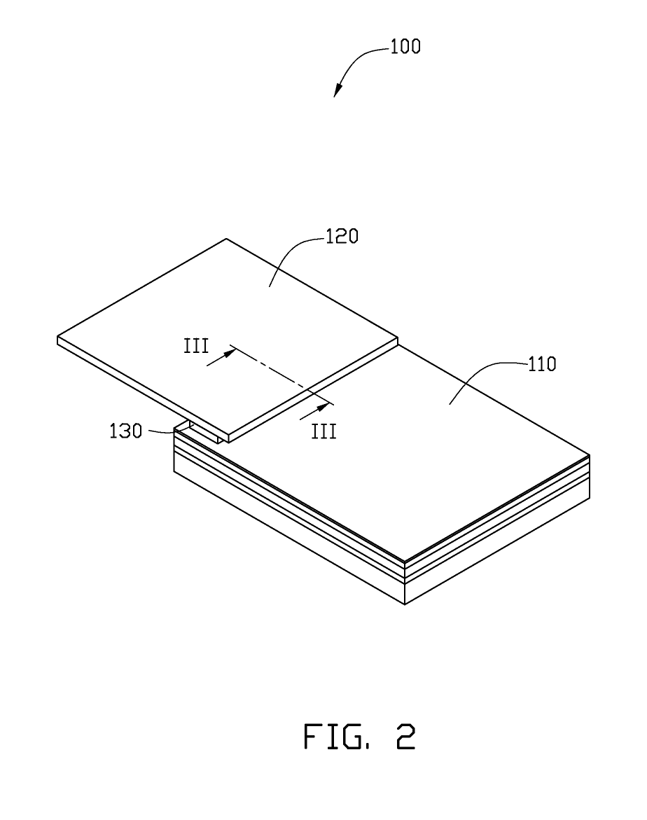

Referring to FIGS. 1-2, a touch screen 100 according to an exemplary embodiment of the present disclosure is shown. The touch screen 100 includes a touch panel 110, an FPC 120, and an anisotropic conductive film (ACF) 130. The ACF 130 is adapted to electrically attach the FPC 120 onto the touch panel 110, thereby enabling signal transmission between the touch panel 110 and the FPC 120.

The touch panel 110 may be a capacitor type, resistor type, infrared type, or ultrasonic type touch panel. In one embodiment, as shown in FIG. 1, the touch panel 110 may include a substrate 111, a first conductive layer 112 formed on the substrate 111, a dielectric layer 113 formed on the first conductive layer 112, a second conductive layer 114 formed on the dielectric layer 113, and a protective layer 116 covering the second conductive layer 114.

The first conductive layer 112, the dielectric layer 113, and the second conductive layer 114 cooperatively form a detection assembly for detecting coordinates of a panel contact.

The first conductive layer 112 may include a plurality of parallel first conductive lines (not shown) each extending along a first axis direction, such as an X-axis direction. The second conductive layer 114 may include a plurality of parallel second conductive lines (not shown) each extending along a second axis direction, such as a Y-axis direction, which is perpendicular to the first axis direction. A plurality of capacitors are formed at crossing areas of the first and second conductive lines.

Ends of the second conductive lines extend to a predetermined bonding region 115. The predetermined bonding region 115 may be defined at an edge of the second conductive layer 114. The predetermined bonding region 115 includes a plurality of parallel bonding electrodes 1151, each of which is electrically connected to an end of a respective second conductive line. The bonding electrodes 1151 can be used as detection terminals, at which signals transmitted within the touch panel 110 are detected. In one embodiment, each bonding electrode 1151 can be conductive silver glue, metal such as copper, or metal alloy such as copper alloy. In particular, the silver glue may include a plurality of silver particles and/or other conductive particles suspended in a base adhesive material.

The protective layer 116 is adapted to protect the detection assembly from damage from external forces or agents, such as oxidation or erosion. In one embodiment, the protective layer 116 can mainly include silicon dioxide. In such embodiment, a thickness of the protective layer 116 can be in the range from 30 nm (nanometers) to 100 nm; for example, 50 nm.

The FPC 120 includes a bonding portion 121 corresponding to the bonding region 115 of the touch panel 110. The bonding portion 121 may be located at an edge portion of the FPC 120, and include a plurality of parallel extending electrodes 1211, commonly referred to as gold fingers. Each extending electrode 1211 corresponds to a respective bonding electrode 1511 of the touch panel 110, and electrically connects to the bonding electrode 1511 via the ACF 130.

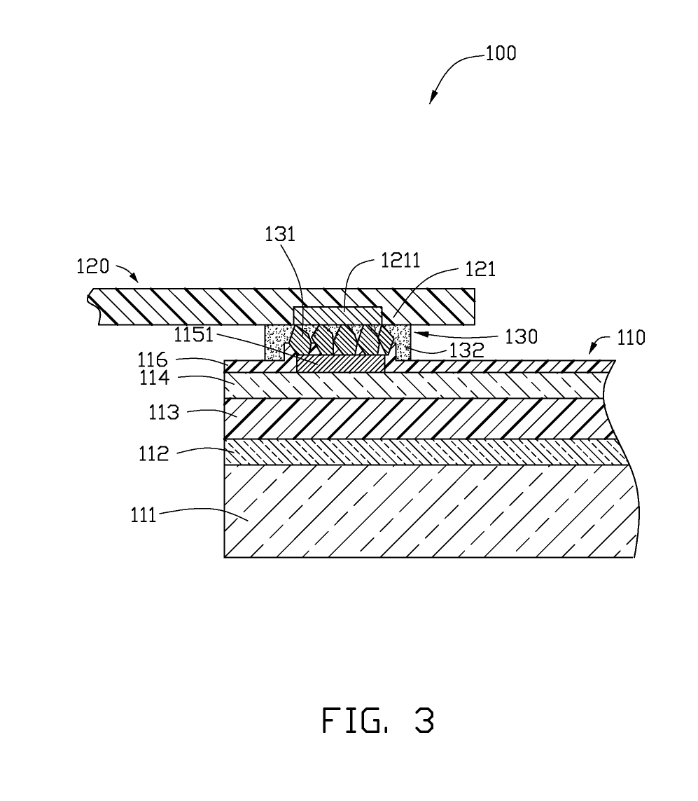

Referring also to FIG. 3, the ACF 130 includes an insulating base film 132, and a plurality of conductive particles 131 distributed therein. A maximum diameter (or a maximum length) of each conductive particle 131 exceeds a thickness of the protective layer 116. In one embodiment, the maximum diameter of each conductive particle 131 can be in the range from 10 μm (micrometers) to 50 μm; and preferably, from 10 μm to 30 μm.

The conductive particles 131 can be rigid irregularly (randomly) shaped particles, with the rigidity exceeding that of at least one of the bonding electrodes 1511 of the touch panel 110 and the extending electrodes 1211 of the FPC 120. For example, in one embodiment, the conductive particles 131 can be carbon particles, nickel particles, or metal alloy particles. It is desired that the rigidity of the conductive particles 131 is sufficient for the conductive particles 131 to penetrate the protective layer 116 of the touch panel 110 upon the condition that a predetermined external force is applied thereto.

With this configuration, when the FPC 120 is bonded to the bonding region 115 of the touch panel 110 using the ACF 130, an end of each conductive particle 131 contacts a corresponding extending electrode 1211 of the FPC 120, and an opposite end of the conductive particle 131 penetrates the protective layer 116 and contacts a corresponding bonding electrode 1511 of the touch panel 110, whereby the extending electrode 1211 and the bonding electrode 1511 are electrically connected. As illustrated, a plurality of the conductive particles 131 may connect each extending electrode 1211 with the corresponding bonding electrode 1511.

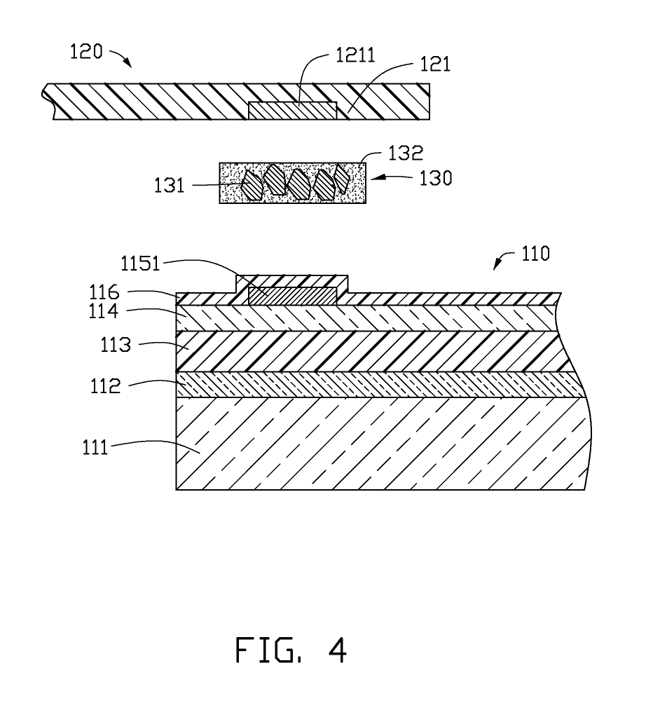

FIGS. 4-6 show successive stages in an exemplary method for bonding an FPC onto a touch panel. The method is as follows.

A touch panel, an FPC, and an ACF are provided, as shown in FIG. 4. Specifically, the touch panel 110, the FPC 120, and the ACF 130 as described in the above embodiment can be adopted in the exemplary method, with details of the touch panel 110, FPC 120, and ACF 130 not repeated here.

The FPC 120 is held above and aligned with the touch panel 110, and the ACF 130 is positioned therebetween.

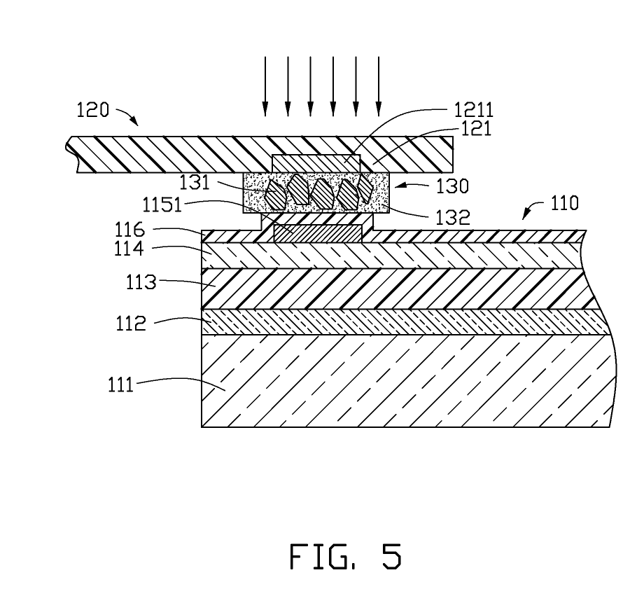

Referring to FIG. 5, in one embodiment, the touch panel 110 can be disposed on a fixture (not shown), and the ACF 130 is positioned corresponding to the bonding region 115 of the touch panel 110. Subsequently, the FPC 120 is placed onto the ACF 130, with each of the extending electrodes 1211 of the FPC 120 aligning with a corresponding bonding electrode 1511 of the bonding region 115.

External force applied impels the FPC 120 towards the touch panel 110, such that certain of the conductive particles 131 penetrate the protective layer 116 of the touch panel 110 and contact the bonding electrodes 1511.

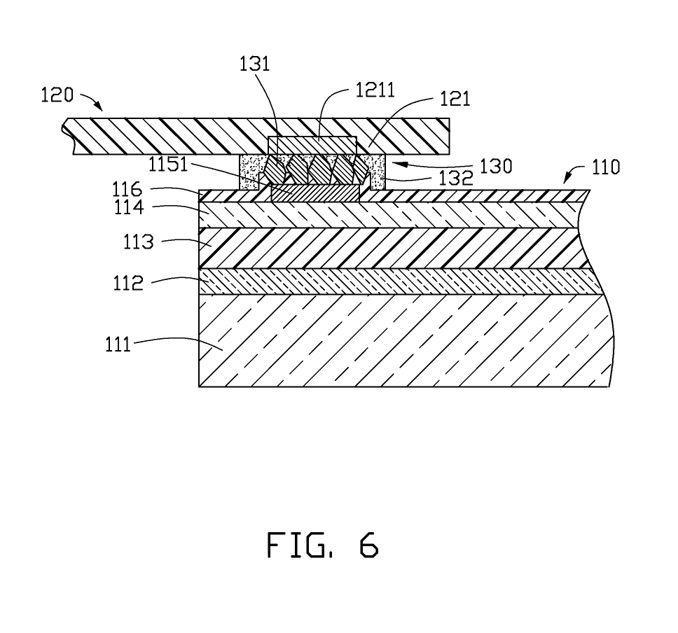

The external force can be provided by a hot bar, and can be transferred to the ACF 130 via the FPC 120. Due to the external force, the insulating base film 132 of the ACF 130 is flattened, and the rigid conductive particles 131 are exposed from the base film 132, such that an end of each conductive particle 131 contacts a corresponding extending electrode 1121. If the external force is sufficiently great, an opposite end of the conductive particle 131 penetrates the protective layer 116 and contacts the corresponding bonding electrode 1511 of the touch panel 110. The extending electrodes 1211 and the corresponding bonding electrodes 1511 are thereby electrically connected with each other via the conductive particles 131, as shown in FIG. 6.

Finally, the external force is removed, and the bonding process for the FPC 120 and the touch panel 110 is finished. Thus, the touch screen 100 as illustrated in FIG. 2 is formed.

As can be seen, in the touch screen 100, the ACF 130 having the rigid conductive particles 131 bonds the FPC 120 to the touch panel 110. Because the conductive particles 131 are rigid and can penetrate the protective layer 116 of the touch panel 110, there is no need to introduce an etching process for the protective layer 116, and thus adjacent elements of the bonding electrodes 1151 are not exposed to the risk of damage during an etching process. In addition, the process of bonding the FPC 120 and the touch panel 110 is simple, and overall manufacturing costs can be conserved.

It is noted that in an exemplary embodiment, the touch panel 110 may further include another bonding region having a plurality of bonding electrodes electrically connected to the first conductive lines of the first conductive layer 112, and these bonding electrodes can also be bonded with another FPC using the configuration and bonding process as described above.

It is also noted that the bonding method provided in the present disclosure can be employed in bonding an FPC onto other kinds of baseboards having a protective layer, such as a printed circuit board, a chip, a display panel, and the like.

It is to be further understood that even though numerous characteristics and advantages of the present embodiments have been set out in the foregoing description, together with other details of the embodiments, the disclosure is illustrative only; and that changes may be made in detail, especially in matters of shape, size and arrangement of parts within the principles of the disclosure to the full extent indicated by the broad general meaning of the terms in which the appended claims are expressed.

What is claimed is:

1. A method for bonding a flexible printed circuit (FPC) onto a baseboard, the baseboard comprising a bonding region comprising a plurality of first electrodes, and a protective layer covering the bonding region, the FPC comprising a plurality of second electrodes, the method comprising:
providing an anisotropic conductive film (ACF) comprising a plurality of conductive particles;
aligning the FPC with the bonding region of the baseboard, and positioning the ACF between the FPC and the baseboard; and
pressing the FPC towards the baseboard, such that first ends of the conductive particles contact respective second electrodes of the FPC, and opposite second ends of the conductive particles penetrate the protective layer and contact the first electrodes of the baseboard corresponding to the respective second electrodes.

2. The method of claim 1, wherein the baseboard comprises a touch panel.

3. The method of claim 1, wherein the conductive particles are rigid particles with irregular shapes.

4. The method of claim 3, wherein the conductive particles are selected from the group consisting of carbon, nickel, and alloy.

5. The method of claim 4, wherein a maximum diameter of each of the conductive particles exceeds the thickness of the protective layer.

6. The method of claim 1, wherein the protective layer comprises silicon dioxide.

7. The method of claim 1, wherein a rigidity of the conductive particles exceeds that of the first electrodes of the touch panel.

8. A touch screen, comprising:
a touch panel comprising a conductive layer, a plurality of first electrodes, and a protective layer covering both the conductive layer and the first electrodes;
a flexible printed circuit (FPC) comprising a plurality of second electrodes; and
an anisotropic conductive film (ACF) bonding the FPC to the touch panel, the ACF comprising a plurality of conductive particles;
wherein each of the second electrodes of the FPC is bonded to a corresponding first electrode of the touch panel via at least one of the conductive particles, with an end of each such conductive particle abutting against the corresponding second electrode of the FPC, and an opposite end of said each such conductive particle penetrating the protective layer and abutting against the corresponding first electrode.

9. The touch screen of claim 8, wherein the conductive particle are rigid particles with irregular shapes.

10. The touch screen of claim 9, wherein the conductive particles are selected from the group consisting of carbon, nickel, and alloy.

11. The touch screen of claim 10, wherein a maximum diameter of said each such conductive particle exceeds the thickness of the protective layer.

12. The touch screen of claim 11, wherein the protective layer comprises silicon dioxide.

13. The touch screen of claim 9, wherein a rigidity of the conductive particle exceeds that of the first electrodes of the touch panel and that of the second electrodes of the FPC.

14. A bonding assembly, comprising:
a baseboard comprising a bonding region and a protective layer covering the bonding region, the bonding region comprising a plurality of electrodes;
a flexible printed circuit (FPC) comprising a plurality of electrical terminals; and
an anisotropic conductive film (ACF) bonding the FPC onto the bonding region of the baseboard, the ACF comprising a plurality of conductive particles;
wherein first ends of the conductive particles mechanically and electrically contact the electrical terminals of the FPC, and opposite second ends of the conductive particles penetrate the protective layer and mechanically and electrically contact the electrodes of the bonding region corresponding to the electrical terminals.

15. The bonding assembly of claim 14, wherein the conductive particle are rigid particles with irregular shapes.

16. The bonding assembly of claim 15, wherein the conductive particles are selected from the group consisting of carbon, nickel, and alloy.

17. The bonding assembly of claim 16, wherein a maximum diameter of each of the conductive particle exceeds the thickness of the protective layer.

18. The bonding assembly of claim 17, wherein the protective layer comprises silicon dioxide.

19. The bonding assembly of claim 14, wherein a rigidity of the conductive particles exceeds that of the electrodes of the bonding region.

20. The bonding assembly of claim 14, wherein the baseboard is selected from the group consisting of a touch panel, a printed circuit board, a display panel, and a chip.
